(19) United States
(12) Patent Application Publication
(10) Pub. No.: US 2007/0079186 A1
(43) Pub. Date: Apr. 5, 2007

(54) Memory device and method of operating memory device

(76) Inventor: Gerhard Risse, Munchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/454,826

(22) Filed: Jun. 16, 2006

(30) Foreign Application Priority Data
Sep. 13, 2005 (DE) 10 2005 043 547.5

(51) Int. Cl. G11C 29/00

(52) U.S. Cl. 714/718

(57) ABSTRACT

A memory module includes a memory core configured to read and write data. A first input interface is configured to receive write or command data from a forward direction and to receive read data from the forward direction. A first output interface is configured to send read data in a reverse direction and to send write or command data in the reverse direction. A second input interface is configured to receive read data from the reverse direction and to receive write or command data from the reverse direction. A second output interface is configured to send write or command data in the forward direction and to send read data in the forward direction.

### CROSS-REFERENCE TO RELATED APPLICATIONS

This Utility Patent Application claims priority to German Patent Application No. DE 10 2005 043 547.5, filed on Sep. 13, 2005, which is incorporated herein by reference.

### BACKGROUND

In the case of write/read memories, such as random access memory (RAM) for computer systems, it is currently common practice to use memory devices which comprise one or more memory modules and which communicate with the other components of the computer system via a memory controller. For example, dual-in-line memory modules (DIMM) of the fully-buffered type may be used. In this case, each memory module comprises, in addition to a memory core, a advanced memory buffer (AMB). The AMB establishes a connection to a memory controller. From a serial data stream between the memory controller and the memory module, the AMB decodes commands and write data and forwards the commands and write data to the memory core via a memory interface. Conversely, the AMB can convert data from the memory core into serial data packets. Furthermore, the AMB comprises passthrough logic, via which write or command data that are intended for another memory module can be passed through the memory module. Moreover, in the case of read commands, read data from the memory core of the memory module can be combined into data packets with merging logic.

Data transmission is effected using a special protocol which is based on two different types of data frame: data frames having write or command data reach the memory modules via a 10-bit wide southbound link; and the memory controller receives response data frames from the memory modules via a 14-bit wide northbound link. Special input and output interfaces are respectively provided for this purpose on the memory controller and on the memory modules. The southbound link transmits data in a forward direction from the memory controller to the memory module, while the northbound link transmits data in a reverse direction from the memory modules to the memory controller.

If the memory device comprises a plurality of memory modules, the modules are typically strung together in a chain, an input interface and an output interface of adjacent memory modules being respectively interconnected for both the southbound link and the northbound link. In this way, write or command data can be transmitted in the forward direction, via the southbound link, from one memory module to the next, while read data is transmitted, via the northbound link, from one memory module to the next, but in the direction opposite to that for the southbound link (i.e., in the reverse direction).

A memory device having memory modules chained together is extremely susceptible to malfunctioning of the AMB of one of the memory modules. In particular, a failed AMB causes, not only failure of the data transmission to the memory module, but also failure of the data transmission to all memory modules located in the forward direction relative to this memory module. Data stored in these memory modules is no longer accessible and, in effect, is lost as a consequence.

Moreover, in typical known chain-type arrangements, there is a long latency time for those memory modules at the greatest distance from the memory controller. Thus, for a memory module disposed at the nth place in the chain, the latency time includes all of the latency times of n point-to-point links. Furthermore, the bandwidth for the data transmission is limited. In order to ensure a certain bandwidth for the data transmission, an example memory device having n memory modules has n high-speed links active. Data frames transmitted in the forward direction are transmitted through the entire chain, even if their destination is the first memory module of the chain. This results in a high power consumption.

Moreover, typical known memory devices having fully-buffered DIMM memory modules, it is only possible to a limited extent to remove or replace a memory module during operation of the memory device. If, for example, the first memory module of the chain (i.e., the memory module nearest to the memory controller) is to be replaced, all memory modules of the chain-type arrangement are deactivated and the data is stored elsewhere.

For these and other reasons there is a need for the present invention.

### SUMMARY

One embodiment provides a memory module including a memory core configured to read and write data. The memory module includes a first input interface configured to receive write or command data from a forward direction and to receive read data from the forward direction. The memory module includes a first output interface configured to send read data in a reverse direction and to send write or command data in the reverse direction. The memory module includes a second input interface configured to receive read data from the reverse direction and to receive write or command data from the reverse direction. The memory module includes a second output interface configured to send write or command data in the forward direction and to send read data in the forward direction.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates, in schematic form, a memory device according to one embodiment.

FIG. 2 illustrates an example first type of read operation for the memory device illustrated in FIG. 1.

FIG. 3 illustrates an example second type of read operation for the memory device illustrated in FIG. 1.

FIG. 4 illustrates an example write operation for the memory device illustrated in FIG. 1.

FIG. 5 illustrates an example removal or replacement of a memory module for the memory device illustrated in FIG. 1.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Embodiments include a memory module, a memory device and a method for operating a memory device. Example embodiments include memory devices of the write/read type that are used, for example, in computer systems as RAM.

One embodiment of memory topology includes a memory controller and at least one memory module configured in a closed ring arrangement in which data can be transmitted in both a forward direction and in a reverse direction.

One embodiment of a memory module comprises a memory core configured to read and write of data, a first input interface configured to receive write or command data from a forward direction, a first output interface configured to send read data in a reverse direction, a second input interface configured to receive read data from the reverse direction, and a second output interface configured to send write or command data in the forward direction. One embodiment of a memory module is capable of receiving, from the forward direction, write or command data from a memory controller, and of sending read data in the reverse direction to the memory controller.

One embodiment of a memory module is configured to receive read data from the forward direction via the first input interface, to send write or command data in the reverse direction via the first output interface, to receive write or command from the reverse direction via the second input interface, and to send read data in the forward direction via the second output interface. In this embodiment, it is possible to transmit write or command data and read data to and from the memory module, in both the forward and reverse directions.

Since both write or command data and read data are transmitted via the input and output interfaces, the two input interfaces and the two output interfaces can be of identical design. Furthermore, a frame-base data transmission, having a single identical frame format, can be used for the write or command data and for the read data.

In one embodiment of a memory module, two different types of read command may be provided. A read command is received in the memory module either from the forward direction or from the reverse direction. The memory module then, in dependence on memory contents of its memory core, generates read data which can be inserted into a data frame received by the data module, with data that is no longer required being able to be overwritten in this data frame. A received data frame may thus contain, for example, write data that has already been stored in another memory module and can therefore be overwritten with read data. The data frame with the inserted read data is then sent in the direction from which it was received.

In an example first type of read command, the read data is sent in the same direction from which the read command was received in the memory module. In an example second type of read command, the read data is sent in the direction other than that from which the read command was received. Whereas the example second type of read command has a variable latency time, which increases with the distance of the memory module from the memory controller (i.e., with the number of further memory modules disposed between the memory module and the memory controller), the example first type of read command offers a latency time that is independent of the position of the memory module.

One embodiment of a memory module is configured to deactivate, upon receipt of a corresponding configuration command, either the first input interface and the first output interface or the second input interface and the second output interface, such that the transmission of write or command data is possible only in either the forward or the reverse direction and the transmission of read data is possible only in either the reverse or the forward direction. This operating mode is provided if the ring arrangement is interrupted, for example in the case of failure of a memory module or in the case of removal or replacement of a memory module.

One embodiment of a memory device includes at least one memory module and one memory controller coupled to each other in a closed ring arrangement, such that write or command data and read data can be transmitted in both the forward direction and in the reverse direction. The reliability can thereby be increased since, in the event of a malfunction or interruption of the transmission, a transmission via the other direction remains possible for one of the directions. Moreover, an increased bandwidth can be assured, since there are respectively two different transmission paths available for both the write or command data and for read data.

In one embodiment, the memory device comprises a plurality of the memory modules that are coupled in as series arrangement. In one embodiment, the closed ring arrangement of memory controller and memory modules can ensure that, in normal operation, each of the memory modules is accessible for write or command data and for read data, both from the forward direction and from the reverse direction. Thus, if, for one of the memory modules, one of the input interfaces or one of the output interfaces fails, or if all input and output interfaces fail, of if the entire memory module fails, the remaining memory modules remain accessible for read and write accesses. Furthermore, it is possible for one of the memory modules in the series arrangement to be removed during operation of the memory device, for example in order to replace the memory module, or to insert a memory module into the series arrangement, without interrupting the operation of the other memory modules.

One embodiment of a memory device has a lower power consumption for a given bandwidth. If, for example, a conventional memory device comprises eight memory modules, each point-to-point link between adjacent memory modules giving rise to a certain power consumption, the total power consumption for the conventional memory device is eight times that power consumption. In example embodiments disclosed herein only one additional point-to-point link (comprising a link for the forward direction and a link for the reverse direction) is employed to close the ring arrangement. In this example embodiment, the power consumption would thus be nine times the power consumption for one point-to-point link. Since, however, as already mentioned, the bandwidth is doubled at the same time with this example embodiment, a substantially lesser power consumption, relative to bandwidth, can be achieved over a conventional memory device. In the case of the example described above, with eight memory modules, the reduction of the power consumption relative to bandwidth would be approximately 44%.

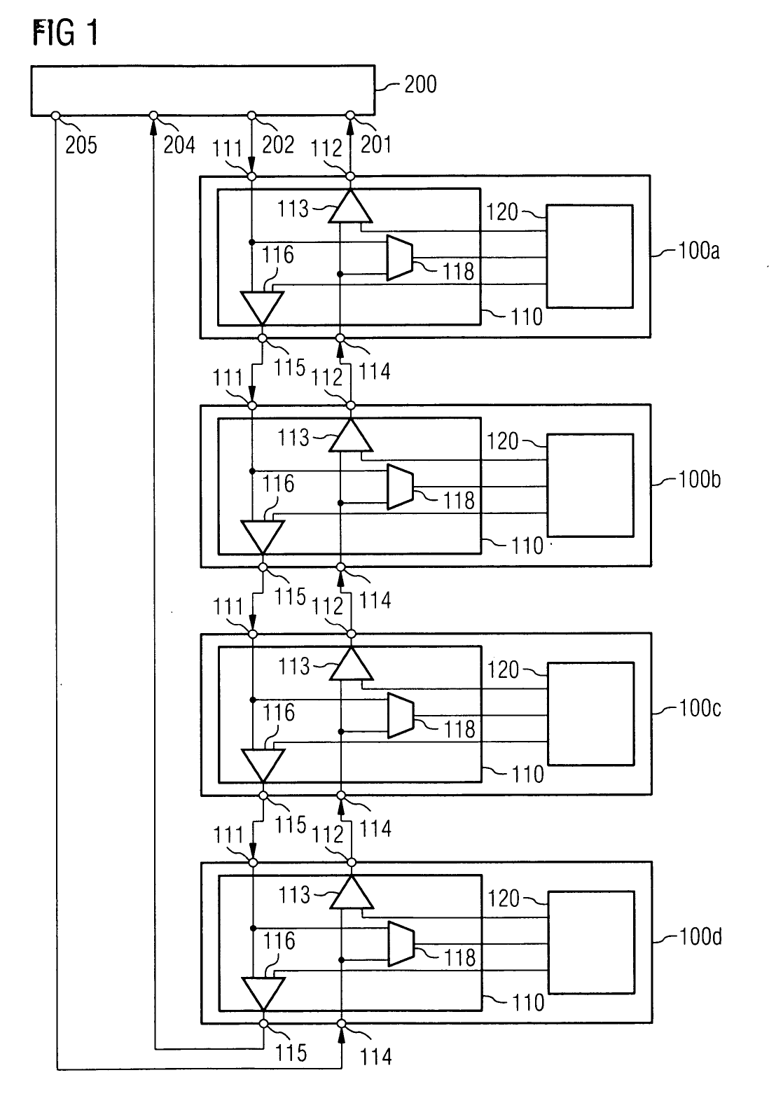

There is described in the following a memory device which can be used, for example in a computer system, as a write/read memory (e.g., RAM). FIG. 1 illustrates a schematic representation of one embodiment of a memory device.

The example memory device embodiment illustrated in FIG. 1 comprises a plurality of memory modules 100a, 100b, 100c, and 100d, which are coupled to each other in a series arrangement. A first memory module 100a and a last memory module 100d of the series arrangement are respectively coupled to a memory controller 200 in a closed ring arrangement.

In the following, the structure of the memory modules 100a, 100b, 100c, 100d is explained by describing the structure of memory module 100a, as memory modules 100b, 100c and 100d can be substantially identical in structure to memory module 100a.

One embodiment of the memory module 100a comprises a memory core 120 for the reading and writing of data. Memory core 120 may be, for example, one or more memory components of the double-data-rate (DDR) type. In particular, memory components of the DDR2 type or DDR3 type, or comparable memory components, may be used. Data may be repeatedly stored and read-out in the memory core 120 (e.g., the memory could be RAM).

Furthermore, memory module 100a comprises an interface block 110, which provides a first input interface 111, a first output interface 112, a second input interface 114, and a second output interface 115. The first input interface 111 receives write or command data from the memory controller 200, from a forward direction. The first output interface 112 sends read data, in a reverse direction, to the memory controller 200. The second input interface 114 receives read data from the reverse direction, and the second output interface 115 sends write or command data in the forward direction.

The input and output interfaces 111, 112, 114, 115 are not limited to a specific data type, however, but can be used both for write or command data and for read data. Thus, read data from a memory module that is adjacent in the reverse direction can also be received via the first input interface 111, and write or command data can be sent via the first output interface 112 to a memory module that is adjacent in the reverse direction. Likewise, write and command data can be received via the second input interface 114 from a memory module that is adjacent in the forward direction or from the memory controller 200, and read data can be sent via the second output interface 115 to a memory module that is adjacent in the forward direction or to the memory controller 200.

In one embodiment, the first output interface and the second output interface each comprise a line driver 113 and 116 respectively, which outputs data (e.g., the write or command data or the read data) in a frame-based transmission format. In this case, data frames having the same frame format are used for the write or command data and for the read data. Apart from the direction of the data transmission, the first input interface 111 and the second input interface 114, and the first output interface 112 and the second output interface 115, can be substantially identical in design.

Via a multiplexer 118, either write or command data from the first input interface 111, or write or command data from the second input interface 114, can be forwarded to the memory core 120. Furthermore, data frames received via the first input interface 111 are forwarded to the second output interface 116, and data frames received via the second input interface 114 are forwarded to the first output interface 112. In the line drivers 113 and 116, read data generated dependent on memory contents of the memory core 120 are inserted into the data frames before the data frames are sent in the reverse direction and in the forward direction. In one embodiment, it is ensured that no data that is still required is inadvertently overwritten.

In the example memory device embodiment illustrated in FIG. 1, the memory controller 200 comprises a first input interface 201, configured to receive read data from the reverse direction from the memory modules 100a, 100b, 100c, 100d, and a first output interface 202 configured to send write or command data in the forward direction to the memory modules 100a, 100b, 100c, 100d. Furthermore, the memory controller 200 comprises a second input interface 204 configured to receive read data from the forward direction from the memory modules 100a, 100b, 100c, 100d, and a second output interface configured to send write or command data in the reverse direction to the memory modules 100a, 100b, 100c, 100d.

In the illustrated embodiment, the first input interface 111 of the first memory module 100a is coupled to the first output interface 202 of the memory controller 200, in order to transmit data in the forward direction. The first output interface 112 of the first memory module 100a is coupled to the first input interface of the memory controller 200, in order to transmit data in the reverse direction. The memory module 100d is the last memory module of the series arrangement of memory modules. The second input interface of the last memory module 100d is coupled to the second output interface 205 of the memory controller 200, in order to transmit data in the reverse direction. The second output interface of the last memory module 100d is coupled to the second input interface 204 of the memory controller 200, in order to transmit data in the forward direction. With regard to the other memory modules 100b, 100c, the first input interface 111 is coupled to the second output interface 115 of a memory module 100a, 100b that is adjacent in the reverse direction, in order to transmit data in the forward direction, the first output interface 112 is coupled to the second input interface 114 of the memory module 100a, 100b that is adjacent in the reverse direction, in order to transmit data in the reverse direction, the second input interface 114 is coupled to the first output interface 112 of a memory module 100c, 100d that is adjacent in the forward direction, in order to transmit data in the reverse direction, and the second output interface 115 is coupled to the first input interface 111 of the memory module 100c, 100d that is adjacent in the forward direction, in order to transmit data in the forward direction. The memory controller 200 and the memory modules 100a, 100b, 100c, 100d thus are configured in a closed ring arrangement in which write or command data and read data can be transmitted, both in the forward direction and in the reverse direction, between the memory controller 200 and each of the memory modules 100a, 100b, 100c, 100d.

In the closed ring arrangement structure of the memory modules 100a, 100b, 100c, 100d and memory controller 200 of the example memory device embodiment illustrated in FIG. 1, a malfunctioning or a failure of the interface block 110 in the case of one of the memory modules 100a, 100b, 100c, 100d does not result in a failure of the entire memory device. Rather, memory modules that are disposed in the reverse direction relative to the malfunctioning memory module continue to be accessible, from the forward direction, for the memory controller 200. Equally, memory modules that are disposed in the forward direction relative to the malfunctioning memory module continue to be accessible, from the reverse direction, for the memory controller 200.

Furthermore, in comparison with a conventional chain-type arrangement of memory modules, the latency time of the example memory device embodiment illustrated in FIG. 1 is limited. Thus, the respectively shorter data path to one of the memory modules 100a, 100b, 100c, 100d can be selected by the memory controller 200. Since respectively two data paths are available for write or command data and for read data, the bandwidth for the data transmission is in effect doubled with the memory device embodiment illustrated in FIG. 1.

In comparison with a conventional chain-type arrangement, the number of point-to-point links for the closed ring arrangement embodiment illustrated in FIG. 1 is only increased by one additional point-to-point link between the last memory module 100d of the series arrangement and the memory controller 200, such that the doubling of the bandwidth does not result in a correspondingly increased power consumption or, conversely, the power consumption is significantly reduced for the same bandwidth.

Furthermore, it is possible for one of the memory modules 100a, 100b, 100c, 100d to be removed during the operation of the memory device without interrupting the operation of the other memory modules for this purpose. In order to replace one of the memory modules 100a, 100b, 100c, 100d, it is thus not necessary to deactivate the entire memory device. It is sufficient to provide a single replacement memory module to take over, during the replacement operation, the function of the memory module that is to be replaced, such that the capacity of the memory device is not impaired. For example, the data of the memory module that is to be replaced can be temporarily stored in the other memory modules of the memory device. A complete replacement memory device is not required. In some embodiments, the costs of the system, the power consumption and the space requirement on a system board are thereby reduced.

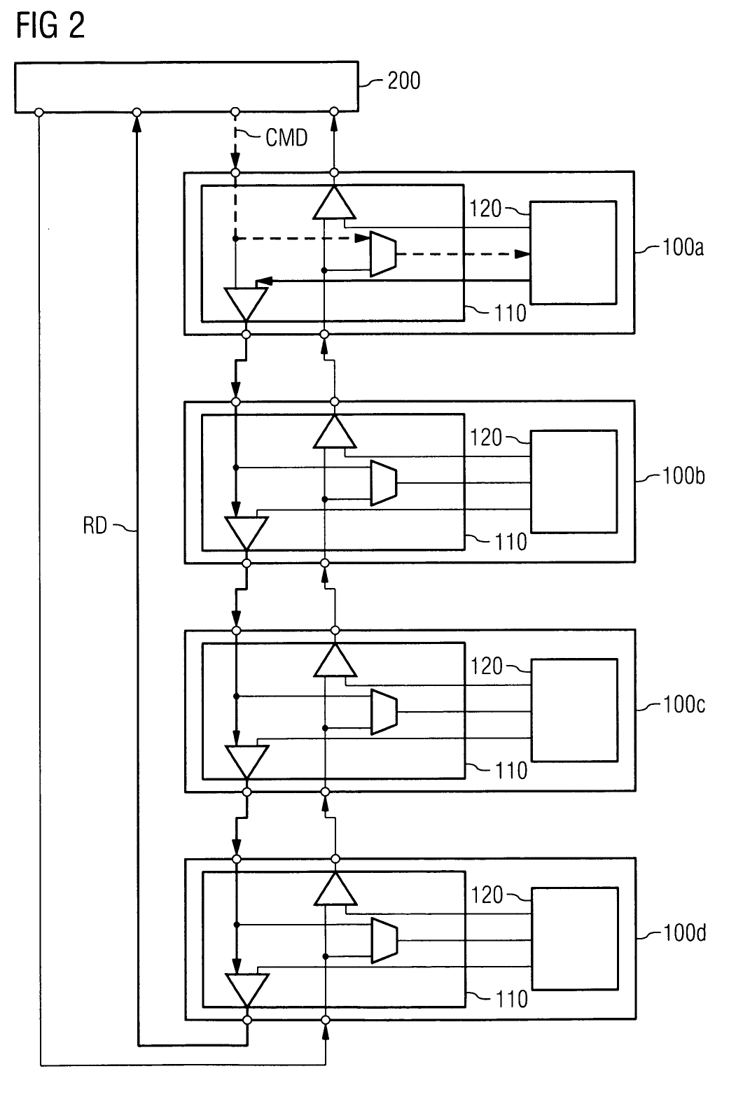

The main processes in example operations of the example memory device embodiment illustrated in FIG. 1 are described below with reference to FIGS. 2-4.

FIG. 2 illustrates an example first type of read operation for the memory device embodiment illustrated in FIG. 1. During the read operation, the memory controller 200 sends, with the write or command data, a first type of read command to the memory module designated for the read operation (e.g., the memory module 100a in this example illustrated in FIG. 2). The interface block 110 of the memory module 100a directs the received read command to the memory core 120 which, is dependent on memory contents stored therein, generates read data which is dependent on memory module 100a in the same direction from which the read command was received. The corresponding data flow is represented in FIG. 2 by arrows that are emphasized by a thicker line, broken-line arrows representing command data CMD, and closed arrows representing the generated read data RD.

In the case of the example first type of read command, the generated read data RD is inserted as rapidly as possible into a data frame which is transmitted through the memory module 100a in the same direction as the data frame in which the read command was received. The memory controller 200 can ensure in this case that no data transmitted in this data frame is inadvertently overwritten. The possibility of overwriting data in the data frame can also be used, however, to transmit the read data RD with a higher priority.

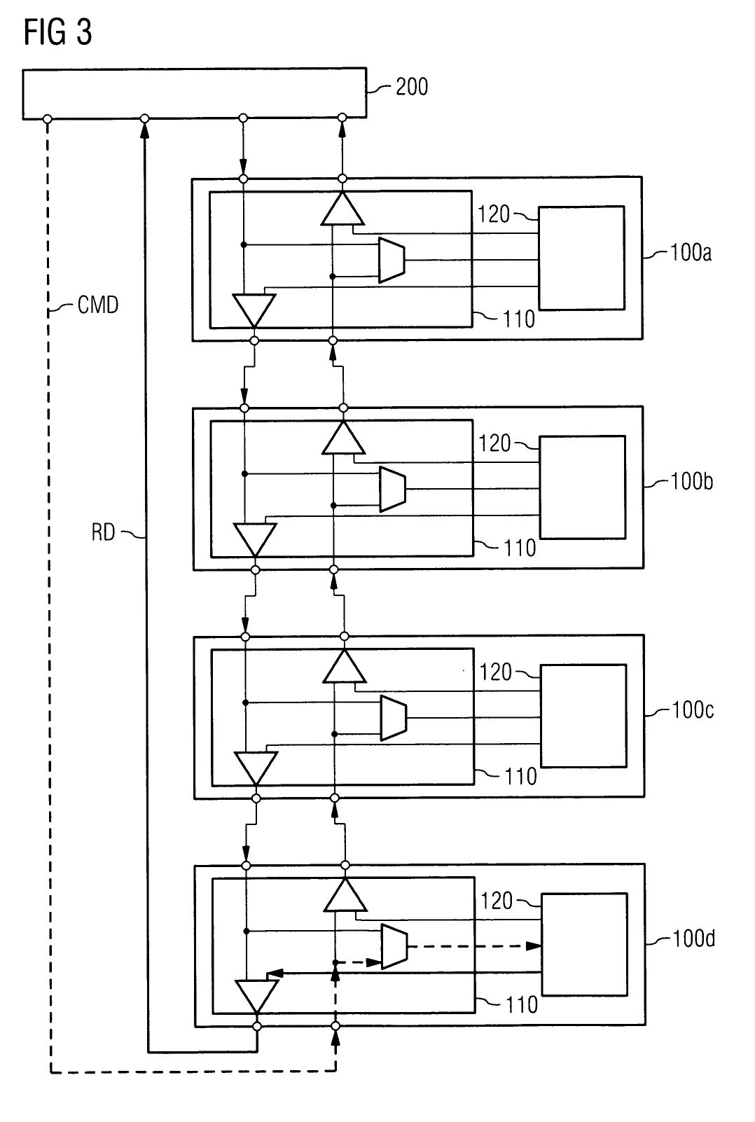

FIG. 3 illustrates an example second type of read operation for the memory device embodiment illustrated in FIG. 1. The data flow is again represented by emphasized arrows, with broken-line arrows representing the command data CMD, and full-line arrows representing the read data RD.

In the case of the example second type of read operation, the memory controller 200 sends a second type of read command to the memory module designated for the read operation (e.g., the memory module 100d in the example illustrated in FIG. 3). The read command is forwarded to the memory core 120 which, dependent on memory data stored therein, generates read data RD which is sent from the memory module 100d in the direction other than that from which the read command was received.

Upon receipt of the example second type of read command, the interface block 110 inserts the generated read data RD as rapidly as possible into a data frame which was received by the memory module 100d from the direction other than the direction of the data frame with which the read command was transmitted. Here again, the memory controller 200 can ensure that no data is inadvertently overwritten in the data frame. The possibility of overwriting data can also be used, however, to transmit the read data RD with a higher priority.

The read operations illustrated in FIGS. 2 and 3 are only example operations and there are many other suitable example operations. For example, it is understood that, for each of the two types of read operation, the read command can be transmitted both in the forward direction and in the reverse direction to the memory module designated for the read operation. Furthermore, each of the memory modules 100a, 100b, 100c, 100d can be read-out through both types of read command.

In the case of the example second type of read command illustrated in FIG. 3, it is possible, however, for reasons of a shorter latency time, to read-out the memory modules 100a, 100b of the half of the series arrangement that is the first half in the forward direction via a read command which is transmitted in the forward direction, while the memory modules 100c, 100d of the half of the series arrangement that is the second half in the forward direction is read-out through a read command which is transmitted in the reverse direction.

In the case of the example first type of read command illustrated in FIG. 2, the latency time, by contrast, is not dependent on the position of the read-out memory module in the series arrangement or on the direction used for transmission of the read command.

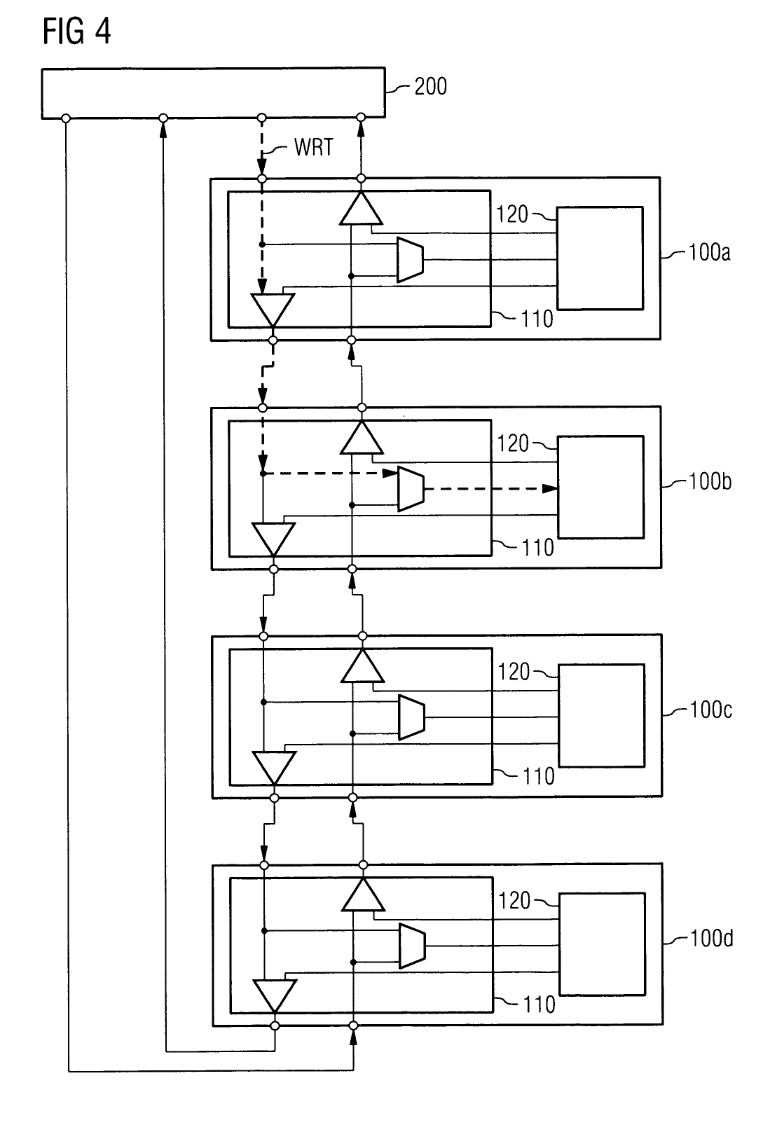

FIG. 4 illustrates an example write operation for the example memory device embodiment illustrated in FIG. 1. The data flow is again represented by emphasized arrows. During the write operation, write data WRT, including a write command, are transmitted from the memory controller 200 to the memory module 100b designated for the write operation.

As soon as the data frame with the write data WRT reaches the interface block 110 of the memory module 100b designated for the write operation, the write data is forwarded out of the data frame to the memory core 120 and stored therein. The data frame is forwarded to the next memory module in the ring arrangement and can be overwritten there with read data.

For the example write operation illustrated in FIG. 4, the write data WRT can be transmitted, either in the forward direction or in the reverse direction, to the memory module designated for the write operation. For reasons of a shorter latency time it is possible, in the case of memory modules 100a, 100b that are located in the first half of the series arrangement in the forward direction, to transmit the write data WRT in the forward direction, while, for the memory modules 100c, 100d that are located in the second half of the series arrangement in the forward direction, it is possible to transmit the write data WRT in the reverse direction.

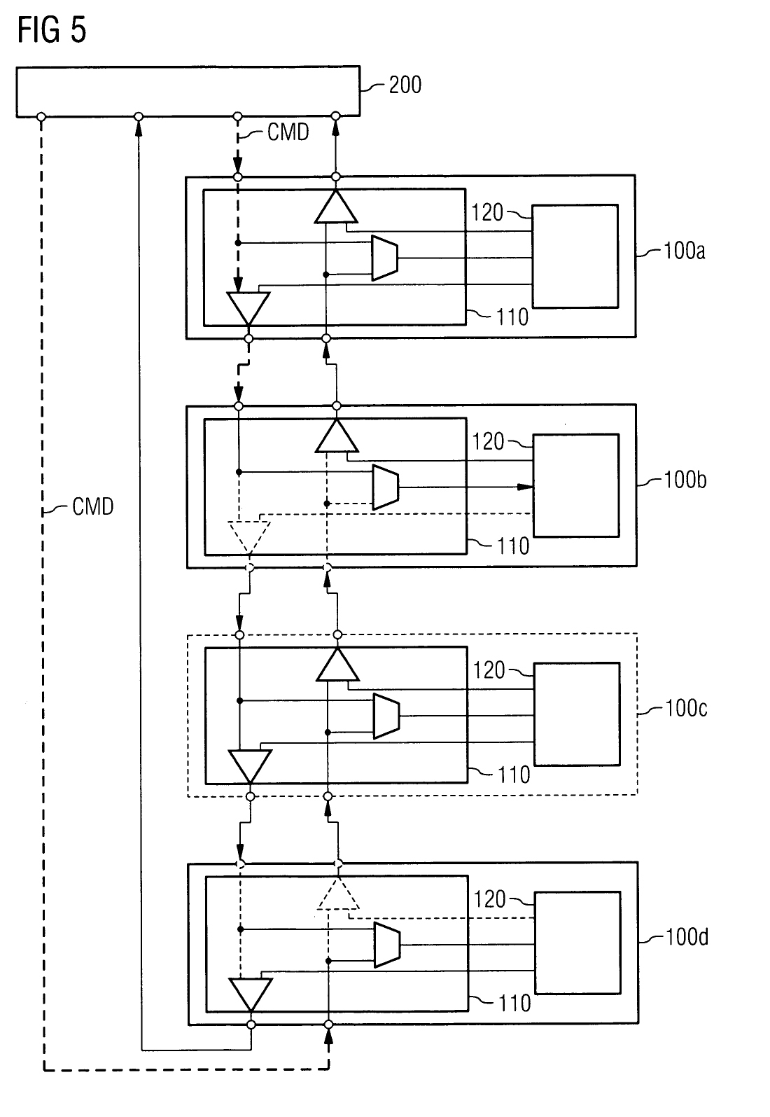

FIG. 5 illustrates an example procedure for the removal or replacement of one of the memory modules 100a, 100b, 100c, 100d of the memory device embodiment illustrated in FIG. 1. FIG. 5 exemplarily represents a situation in which the memory module 100c is removed or replaced (represented by a broken-line enclosure of the memory module 100c). For example, the memory controller 200 may have previously detected a malfunctioning of the memory module 100c. In this case, it is no longer possible for data transmission to be effected from the memory module 100b to the memory module 100d via the memory module 100c.

In this case, a corresponding configuration command that is sent in the forward direction from the memory controller 200 to the memory module 100b commands the memory module 100b into an alternative operating mode in which the input interface and output interface adjacent to the memory module 100c that is to be removed or replaced are deactivated. This is represented in FIG. 5 by broken-line structures within the memory module 100b.

Accordingly, the memory module 100d, which is adjacent in the forward direction to the memory module 100c that is to be removed or replaced, is put by the memory controller 200, via a corresponding configuration command, into an alternative operating mode in which the input interface and the output interface adjacent to the memory module 100c that is to be removed or replaced are likewise deactivated. This is again represented by broken-line structures within the memory module 100d.

In this state, the memory module 100c can then be removed or replaced. As illustrated by FIG. 5, the removal of the memory module 100c divides the closed ring arrangement into two chain-type arrangements in which only example read operations of the second type described with reference to FIG. 3 are possible.

In the case of memory devices of the type described above, for computer systems, it is usual for corresponding slots to be provided for the memory modules 100a, 100b, 100c, 100d on a system board of the computer system. The memory controller 200 is usually provided as a component of the system board. The links, described with reference to FIG. 1, between the memory controller 200 and the memory modules 100a, 100b, 100c, 100d would thus be provided through corresponding links on the system board. The closed ring arrangement can then be assured, on the one hand, in that all slots provided for the ring arrangement are occupied by memory modules. On the other hand, it is possible to use a lesser number of memory modules, in that unused slots are fitted with a blind module. A blind module may be implemented, for example, by a printed-circuit board which has contacts corresponding to the memory modules and which connects the contacts corresponding to the first input interface to the contacts corresponding to the second output interface, and connects the contacts corresponding to the second input interface to the contacts corresponding to the first output interface, in order to close the ring arrangement both in the forward direction and in the reverse direction.

If, as explained with reference to FIG. 5, the closed ring arrangement has been opened, and a memory module has been removed, replaced or added, such that the ring arrangement is now physically re-closed, the memory controller 200 sends a further configuration command to those memory modules that are adjacent to the position of the removed, replaced or added memory module (e.g., in the case of the example of FIG. 5, to the memory modules 100b and 100d) in order to reactivate the input interface and the output interface respectively adjacent to the removed, replaced, or inserted memory module. A training procedure is then performed for the data transmission between these memory modules and the new adjacent memory module. In this case, the new adjacent memory module may be either a replaced or a newly added memory module, or a memory module already contained in the ring arrangement, if a blind module is used instead of the removed memory module as described above.

There has thus been described above a memory device and a method for operating the memory device, in which memory device and method a high reliability can be assured through use of a closed ring arrangement in which data can be transmitted both in the forward direction and in the reverse direction. In particular, the memory device can continue to be operated even if the interface block 110 fails at one of the memory modules. In the case of a failure, or for maintenance purposes, the ring arrangement can be divided into two chain-type arrangements, and it is possible to replace each of the individual memory modules while the other memory modules remain in operation.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory module, comprising:
a memory core configured to read and write data;
a first input interface configured to receive write or command data from a forward direction and to receive read data from the forward direction;
a first output interface configured to send read data in a reverse direction and to send write or command data in the reverse direction;
a second input interface configured to receive read data from the reverse direction and to receive write or command data from the reverse direction; and
a second output interface configured to send write or command data in the forward direction and to send read data in the forward direction.

2. The memory module according to claim 1, wherein the first input interface and the second input interface are of substantially identical design, and the first output interface and the second output interface are of substantially identical design.

3. The memory module according to claim 1, wherein the first input interface, the second input interface, the first output interface and the second output interface are configured to handle a frame-based data transmission with an identical frame format.

4. The memory module according to claim 3, comprising:
logic configured, upon receipt of a read command in the write or command data either from the forward direction or from the reverse direction, to generate read data dependent on memory contents of the memory core, to insert the read data into a received data frame, and to send the data frame in the same direction from which it was received.

5. The memory module according to claim 1, comprising:
logic configured, upon receipt of a read command in the write or command data either from the forward direction or from the reverse direction, to generate read data dependent on memory contents of the memory core, to send, in response to a first type of the read command, the read data in the same direction as that from which the read command was received, and to send, in response to a second type of the read command, the read data in the direction other than the direction from which the read command was received.

6. The memory module according to claim 1, comprising:
a multiplexer configured to couple a data input of the memory core to the first input interface and to the second input interface.

7. The memory module according to claim 1, comprising:
logic configured, upon receipt of a corresponding configuration command in the write or command data, to deactivate either the first input interface and the first output interface or to deactivate the second input interface and the second output interface.

8. A memory device, comprising:
at least one memory module comprising:
a memory core configured to read and write data;
a first input interface configured to receive write or command data from a forward direction and to receive read data from the forward direction;
a first output interface configured to send read data in a reverse direction and to send write or command data in the reverse direction;
a second input interface configured to receive read data from the reverse direction and to receive write or command data from the reverse direction; and
a second output interface configured to send write or command data in the forward direction and to send read data in the forward direction; and
a memory controller comprising:
a first input interface configured to receive read data, from the reverse direction, from the at least one memory module;
a first output interface configured to send write or command data, in the forward direction, to the at least one memory module;
a second input interface configured to receive read data from the forward direction from the at least one memory module; and
a second output interface configured to send write or command data in the reverse direction to the at least one memory module.

9. The memory device according to claim 8, wherein the memory controller and the at least one memory module are configured in a closed ring arrangement configured to transmit data in the forward direction and in the reverse direction.

10. The memory device according to claim 8, wherein the at least one memory module comprises:
a plurality of the memory modules that are coupled to each other in a series arrangement.

11. The memory device according to claim 10, wherein:
the first input interface of a first memory module of the series arrangement is coupled to the first output interface of the memory controller to facilitate transmitting data in the forward direction;
the first output interface of the first memory module of the series arrangement is coupled to the first input interface of the memory controller to facilitate transmitting data in the reverse direction;
the second input interface of a last memory module of the series arrangement is coupled to the second output interface of the memory controller to facilitate transmitting data in the reverse direction; and
the second output interface of the last memory module of the series arrangement is coupled to the second input interface of the memory controller to facilitate transmitting data in the forward direction; and
wherein, for the other memory modules of the series arrangement:
the first input interface is coupled to the second output interface of a memory module that is adjacent in the reverse direction, to facilitate transmitting data in the forward direction;
the first output interface is coupled to the second input interface of the memory module that is adjacent in the reverse direction, to facilitate transmitting data in the reverse direction;
the second input interface is coupled to the first output interface of a memory module that is adjacent in the forward direction, to facilitate transmitting data in the reverse direction; and
the second output interface is coupled to the first input interface of the memory module that is adjacent in the forward direction, to facilitate transmitting data in the forward direction.

12. The memory device according to claim 10, wherein the memory modules of the series arrangement each comprise:
logic configured, upon receipt of a corresponding command in the write or command data from either the forward direction or the reverse direction, to perform a training procedure for the data transmission with a memory module that is adjacent in a direction different than from which the command was received.

13. A method of operating a memory device, the method comprising:
sending write or command data in a forward direction from a memory controller of the memory device to at least one memory module of the memory device;
receiving read data in the memory controller, from a reverse direction, from the at least one memory module;
sending write or command data in the reverse direction from the memory controller to the at least one memory module; and
receiving read data in the memory controller, from the forward direction, from the at least one memory module.

14. The method according to claim 13, comprising:
receiving a read command with the write or command data in the at least one memory module from either the forward direction or the reverse direction;
generating read data dependent on memory contents of a memory core of the at least one memory module; and
sending the read data from the at least one memory module to the memory controller in a direction different than from which the read command was received.

15. The method according to claim 13, comprising:
receiving a read command in the write or command data in the at least one memory module from either the forward direction or the reverse direction;
generating read data dependent on memory contents of a memory core of the at least one memory module;
sending the read data from the at least one memory module to the memory controller in the same direction as from which the read command was received.

16. The method according to claim 13, comprising:
receiving a write command in the write or command data in the at least one memory module from either the forward direction or the reverse direction; and
generating memory contents of a memory core of the at least one memory module dependent on write data in the write or command data.

17. The method according to claim 13, wherein the memory device comprises a plurality of the at least one memory module that are coupled to each other in a series arrangement, wherein the method comprises:
removing one of the memory modules during the operation of the memory device.

18. The method according to claim 17, comprising:
transmitting, in the reverse direction, write or command data to a memory module that is located in the forward direction relative to the removed memory module; and
transmitting, in the forward direction, read data from the memory module that is located in the forward direction relative to the removed memory module.

19. The method according to claim 17, comprising:
transmitting, in the forward direction, write or command data to a memory module that is located in the reverse direction relative to the removed memory module; and
transmitting, in the reverse direction, read data from the memory module that is located in the reverse direction relative to the removed memory module.

20. The method according to claim 13, wherein the memory device comprises a plurality of the at least one memory module that are coupled to each other in a series arrangement, wherein the method comprises:
inserting of one of the memory modules during the operation of the memory device.

21. The method according to claim 20, comprising:
transmitting, in the reverse direction, write or command data to a memory module that is located in the forward direction relative to the memory module to be inserted; and
transmitting, in the forward direction, read data from the memory module that is located in the forward direction relative to the memory module to be inserted.

22. The method according to claim 20, comprising:
transmitting, in the forward direction, write or command data to a memory module that is located in the reverse direction relative to the memory module to be inserted; and
transmitting, in the reverse direction, read data from the memory module that is located in the reverse direction relative to the memory module to be inserted.

23. The method according to claim 20, comprising:
training of the data transmission between the inserted memory module and an adjacent one of the memory modules.

24. A memory controller for a memory device, the memory controller comprising:
a first input interface configured to receive read data from a reverse direction;
a first output interface configured to send write or command data in a forward direction;
a second input interface configured to receive read data from the forward direction; and
a second output interface configured to send write or command in the reverse direction.

25. The memory controller of claim 24, wherein the memory controller is configured with at least one memory module of the memory device to be in a closed ring arrangement configured to transmit data in the forward direction and in the reverse direction.

26. A memory device comprising:
at least one memory module comprising:
means for reading and writing data;
means for receiving write or command data and read data from a forward direction;
means for sending read data and write or command data in a reverse direction;
means for receiving read data and write or command data from the reverse direction; and
means for sending write or command data and read data in the forward direction; and
a memory controller comprising:
means for receiving read data, from the reverse direction, from the at least one memory module;
means for sending write or command data, in the forward direction, to the at least one memory module;
means for receiving read data from the forward direction from the at least one memory module; and
means for sending write or command data in the reverse direction to the at least one memory module.
